(19) United States
(12) Patent Application Publication
(10) Pub. No.: US 2024/0175905 A1
(43) Pub. Date: May 30, 2024

(54) METER VOLTAGE FINGERPRINT

(71) Applicant: Utilidata, Inc., Providence, RI (US)

(72) Inventors: Zebediah Engberg, Mt. Pleasant, UT (US); Taylor Spalt, Richmond, VA (US)

(73) Assignee: Utilidata, Inc., Providence, RI (US)

(21) Appl. No.: 18/207,464

(22) Filed: Jun. 8, 2023

Related U.S. Application Data
(60) Provisional application No. 63/428,471, filed on Nov. 29, 2022.
(60) Provisional application No. 63/453,218, filed on Mar. 20, 2023.

(51) Int. Cl. G01R 22/06

(52) U.S. Cl. CPC G01R 22/061

(57) ABSTRACT

Meter voltage fingerprint is provided. A system can include a metering system at a location downstream from a substation on a utility grid that distributes electricity. The metering system can receive data samples of a voltage waveform corresponding to the electricity distributed at the location. The metering system can determine first metrics for the voltage waveform over a time interval via a statistical technique. The metering system can determine second metrics for the voltage waveform over the time interval based on a difference between the voltage waveform and a model waveform. The metering system can construct a data structure comprising the first metrics, the second metrics, and an identifier for the location. The metering system can provide the data structure to a data processing system remote from the metering system to cause the data processing system to evaluate a performance of the utility grid.

### CROSS-REFERENCES TO RELATED APPLICATIONS

This application claims the benefit of priority under 35 U.S.C. § 119 to U.S. Provisional Patent Application No. 63/428,471, filed Nov. 29, 2022, and U.S. Provisional Patent Application No. 63/453,218, filed Mar. 20, 2023, each of which is hereby incorporated by reference herein in its entirety.

### FIELD OF THE DISCLOSURE

This disclosure relates generally to systems and methods for a meter voltage fingerprint. In particular, the systems and methods of this disclosure can identify a location on a grid according to voltage fingerprint.

### BACKGROUND

Utility distribution grids can use meters to observe or measure utility delivery or consumption in the grid. These meters, among other components at the grid edge within utility distribution grids, can measure power consumption over time.

### BRIEF SUMMARY OF THE DISCLOSURE

Systems and methods of this disclosure are directed to characterizing or identifying a location on the grid based on a meter voltage fingerprint. The voltage supplied from the utility grid may vary due to differences in at least one of the infrastructures of the utility grid or the loads at the grid edge (e.g., edge device, such as a meter). For example, the infrastructure can include at least a distance from a power source or power generator to the grid edge, various types of equipment throughout the utility grid, or other factors contributing to the transmission or distribution of electric power from the power source to the grid edge. The loads at the grid edge can depend on desired electricity consumption by individual entities or any power generation (e.g., solar panels or generator) contributing to reducing power consumption for the grid edge(s). The devices at the grid edge can compute the root-mean-square (RMS) voltage over a time interval, corresponding to an average of the voltage measured over the respective time interval.

Due to these differences, time-varying characteristics of the voltage can be measured to identify (e.g., uniquely) a location on the utility grid. Further, the measurements or RMS voltages from the edge devices may often be measured or computed at a relatively low time resolution. The systems and methods of the technical solution can provide an example set of characteristics (e.g., sometimes referred to as fingerprints or parameters) used for the identification of the location. The characteristics can be created or generated by measuring the voltage (e.g., at the grid edge) with a relatively high time resolution (e.g., at or above 1 kHz or 10 kHz sampling rate). Subsequently, a data processing system can be configured with computational power to process the high-resolution voltage waveforms at the edge. Data processing (e.g., distilling information into a set of metrics or tables) at the edge can be performed to minimize high bandwidth consumption or network traffic when transmitting relatively high-resolution data, for instance, to a cloud device or server. Thus, the systems and methods of the technical solution discussed herein can perform voltage characterization to identify the unique characteristic of the voltage available given the bandwidth constraint due to the distillation/filtering of data (e.g., a set of metrics or tables) computed at the edge for localization within the utility grid.

In one aspect, this disclosure is directed to a system for meter voltage fingerprint. The system can include a metering system at a location downstream from a substation on a utility grid that distributes electricity. The metering system can include memory and one or more processors. The metering system can receive data samples of a voltage waveform corresponding to the electricity distributed at the location. The metering system can determine a first plurality of metrics for the voltage waveform over a time interval via a statistical technique. The metering system can determine a second plurality of metrics for the voltage waveform over the time interval based on a difference between the voltage waveform and a model waveform. The metering system can construct a data structure comprising the first plurality of metrics, the second plurality of metrics, and an identifier for the location. The metering system can provide the data structure to a data processing system remote from the metering system to cause the data processing system to evaluate a performance of the utility grid.

The metering system can generate the model waveform based on a sinusoidal waveform. The metering system can fit a sinusoidal waveform to the voltage waveform to generate the model waveform.

The data structure can include a plurality of data structures. The metering system can generate a first data structure of the plurality of data structures with first values for the first plurality of metrics over a first time interval of the voltage waveform, and first values for the second plurality of metrics over the first time interval of the voltage waveform. The metering system can generate a second data structure of the plurality of data structures with second values for the first plurality of metrics over a second time interval of the voltage waveform, and second values for the second plurality of metrics over the second time interval of the voltage waveform. The metering system can generate a third data structure of the plurality of data structures with third values for the first plurality of metrics over a third time interval of the voltage waveform, and third values for the second plurality of metrics over the third time interval of the voltage waveform. The metering system can provide the data structure comprising the plurality of data structures to the data processing system over a batch upload process.

The system can include a second metering system at a second location on the utility grid. The second metering system can generate a second data structure with values for the first plurality of metrics over the time interval of a second voltage waveform, and values for the second plurality of metrics over the time interval of the second voltage waveform. The second metering system can provide the second data structure to the data processing system. The system can include a third metering system at a third location on the utility grid. The third metering system can generate a third data structure with values for the first plurality of metrics over the time interval of a third voltage waveform, and values for the second plurality of metrics over the time interval of the third voltage waveform. The third metering system can provide the third data structure to the data processing system.

The data processing system can determine a topological relationship between the metering system, the second metering system, and the third metering system based on the data structure, the second data structure, and the third data structure. The metering system can include one or more sensors to measure the voltage waveform to provide the data samples. The metering system can be communicatively coupled with one or more sensors, the one or more sensors to measure the voltage waveform to provide the data samples.

The metering system can generate at least one of the second plurality of metrics based on an error metric between the voltage waveform and the model waveform fit based on a sinusoidal waveform to the voltage waveform. The metering system can generate at least one of the second plurality of metrics based on at least one of a mean amplitude or a mean frequency of the model waveform fit based on a sinusoidal waveform to the voltage waveform.

In another aspect, this disclosure is directed to a method for meter voltage fingerprint. The method can include receiving, by a metering system comprising memory and one or more processors, data samples of a voltage waveform corresponding to the electricity distributed at the location, the metering system at a location downstream from a substation on a utility grid that distributes electricity. The method can include determining, by the metering system, a first plurality of metrics for the voltage waveform over a time interval via a statistical technique. The method can include determining, by the metering system, a second plurality of metrics for the voltage waveform over the time interval based on a difference between the voltage waveform and a model waveform. The method can include constructing, by the metering system, a data structure comprising the first plurality of metrics, the second plurality of metrics, and an identifier for the location. The method can include providing, by the metering system, the data structure to a data processing system remote from the metering system to cause the data processing system to evaluate a performance of the utility grid.

The method can include generating, by the metering system, the model waveform based on a sinusoidal waveform. The method can include fitting, by the metering system, a sinusoidal waveform to the voltage waveform to generate the model waveform.

The data structure can include a plurality of data structures. The method can include generating, by the metering system, a first data structure of the plurality of data structures with first values for the first plurality of metrics over a first time interval of the voltage waveform, and first values for the second plurality of metrics over the first time interval of the voltage waveform. The method can include generating, by the metering system, a second data structure of the plurality of data structures with second values for the first plurality of metrics over a second time interval of the voltage waveform, and second values for the second plurality of metrics over the second time interval of the voltage waveform. The method can include generating, by the metering system, a third data structure of the plurality of data structures with third values for the first plurality of metrics over a third time interval of the voltage waveform, and third values for the second plurality of metrics over the third time interval of the voltage waveform. The method can include providing, by metering system, the data structure comprising the plurality of data structures to the data processing system over a batch upload process.

The method can include generating, by a second metering system at a second location on the utility grid, a second data structure with values for the first plurality of metrics over the time interval of a second voltage waveform, and values for the second plurality of metrics over the time interval of the second voltage waveform. The method can include providing, by the second metering system, the second data structure to the data processing system. The method can include generating, by a third metering system at a third location on the utility grid, a third data structure with values for the first plurality of metrics over the time interval of a third voltage waveform, and values for the second plurality of metrics over the time interval of the third voltage waveform. The method can include providing, by the third metering system, the third data structure to the data processing system.

The method can include determining, by the data processing system, a topological relationship between the metering system, the second metering system, and the third metering system based on the data structure, the second data structure, and the third data structure. The method can include detecting, by one or more sensors of the metering system, the voltage waveform to provide the data samples. The metering system can be communicatively coupled with one or more sensors. The method can include detecting, by the one or more sensors, the voltage waveform to provide the data samples.

In yet another aspect, this disclosure is directed to a non-transitory computer readable storage medium for meter voltage fingerprint. A non-transitory computer readable storage medium can include processor executable instructions that, when executed by one or more processors of a metering system, cause the metering system to: receive data samples of a voltage waveform corresponding to the electricity distributed at the location; determine a first plurality of metrics for the voltage waveform over a time interval via a statistical technique; determine a second plurality of metrics for the voltage waveform over the time interval based on a difference between the voltage waveform and a model waveform; construct a data structure comprising the first plurality of metrics, the second plurality of metrics, and an identifier for the location; and provide the data structure to a data processing system remote from the metering system to cause the data processing system to evaluate a performance of a utility grid.

The instructions further comprise instructions to generate the model waveform based on a sinusoidal waveform.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE FIGURES

The accompanying drawings are not intended to be drawn to scale. Like reference numbers and designations in the various drawings indicate like elements having similar structure or functionality. For purposes of clarity, not every component may be labeled in every drawing. In the drawings:

FIG. 1 is a block diagram depicting an illustrative utility grid, in accordance with an implementation;

FIG. 2 is a block diagram illustrating an example system to identify a location on a grid according to a voltage fingerprint, in accordance with an implementation;

FIG. 3 is a flow diagram of an example method for identifying a location on a grid according to a voltage fingerprint, in accordance with an implementation; and

FIG. 4 is a block diagram illustrating an architecture for a computer system that can be employed to implement elements of the systems and methods described and illustrated herein, including, for example, aspects of the utility grid depicted in FIG. 1, the system depicted in FIG. 2, and the operations depicted in FIG. 3.

The features and advantages of the present solution will become more apparent from the detailed description set forth below when taken in conjunction with the drawings, in which like reference characters identify corresponding elements throughout. Other features, aspects, and advantages of the subject matter will become apparent from the description, the drawings, and the claims.

### DETAILED DESCRIPTION

Following below are more detailed descriptions of various concepts related to, and implementations of, methods, apparatuses, and systems of meter voltage fingerprint. The various concepts introduced above and discussed in greater detail below may be implemented in any of numerous ways.

A utility grid, or utility distribution system, can distribute electricity. The electricity (e.g., voltage or current) supplied from a utility grid (e.g., electric distribution system) may vary in characteristic (e.g., amplitude, frequency, phase, or period, among other types of characteristics) due to differences in at least one of the infrastructures (e.g., distance from the power generator to the grid edge, types of equipment distributing electricity, etc.) or the loads at the grid edge (e.g., electricity consumption or power generation at the edge). Due to these differences, time-varying characteristics of the voltage can be measured to uniquely identify a location on the utility grid. The systems and methods of the technical solution can measure the voltage at the grid edge(s) with a relatively high time resolution (e.g., at or above 10 kHz sampling rate) to generate a set of characteristics of the voltage. The systems and methods can include a metering system configured to process the high-resolution voltage waveforms at the edge. By performing data processing at the edge, bandwidth consumption or network traffic can be minimized (e.g., distilling information to be sent to the metering system). Thus, the systems and methods of the technical solution discussed herein can perform voltage characterization to identify the unique characteristic of the voltage for localization within the utility grid.

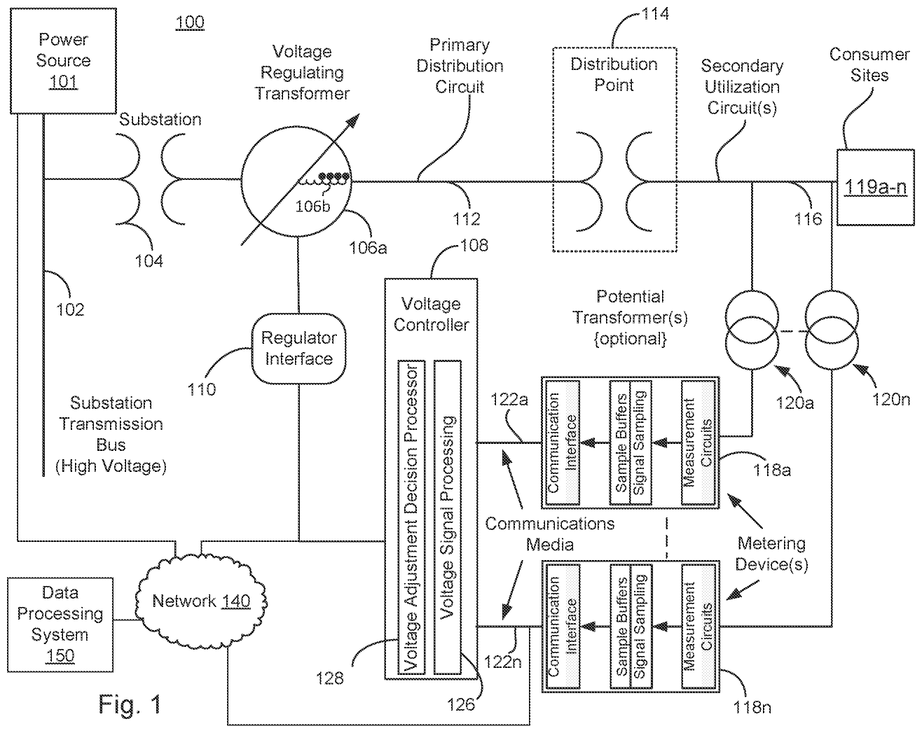

FIG. 1 illustrates an example utility distribution environment. The utility distribution environment can include a utility grid 100. The utility grid 100 can include an electricity distribution grid with one or more devices, assets, or digital computational devices and systems, such as a data processing system 150. In brief overview, the utility grid 100 includes a power source 101 that can be connected via a subsystem transmission bus 102 and/or via substation transformer 104 to a voltage regulating transformer 106a. The voltage regulating transformer 106a can be controlled by voltage controller 108 with regulator interface 110. Voltage regulating transformer 106a can be optionally coupled on primary distribution circuit 112 via optional distribution transformer 114 to secondary utilization circuits 116 and to one or more electrical or electronic devices 119. Voltage regulating transformer 106a can include multiple tap outputs 106b with each tap output 106b supplying electricity with a different voltage level. The utility grid 100 can include monitoring devices 118a-118n that can be coupled through optional potential transformers 120a-120n to secondary utilization circuits 116. The monitoring or metering devices 118a-118n can detect (e.g., continuously, periodically, based on a time interval, responsive to an event or trigger) measurements and continuous voltage signals of electricity supplied to one or more electrical devices 119 connected to circuit 112 or 116 from a power source 101 coupled to bus 102. A voltage controller 108 can receive, via a communication media 122, measurements obtained by the metering devices 118a-118n, and use the measurements to make a determination regarding a voltage tap settings, and provide an indication to regulator interface 110. The regulator interface can communicate with voltage regulating transformer 106a to adjust an output tap level 106b.

The utility grid 100 can include a power source 101. The power source 101 can include a power plant such as an installation configured to generate electrical power for distribution. The power source 101 can include an engine or other apparatus that generates electrical power. The power source 101 can create electrical power by converting power or energy from one state to another state. In some embodiments, the power source 101 can be referred to or include a power plant, power station, generating station, powerhouse or generating plant. In some embodiments, the power source 101 can include a generator, such as a rotating machine that converts mechanical power into electrical power by creating relative motion between a magnetic field and a conductor. The power source 101 can use one or more energy source to turn the generator including, e.g., fossil fuels such as coal, oil, and natural gas, nuclear power, or cleaner renewable sources such as solar, wind, wave and hydroelectric.

In some embodiments, the utility grid 100 includes one or more substation transmission bus 102. The substation transmission bus 102 can include or refer to transmission tower, such as a structure (e.g., a steel lattice tower, concrete, wood, etc.), that supports an overhead power line used to distribute electricity from a power source 101 to a substation 104 or distribution point 114. Transmission towers 102 can be used in high-voltage AC and DC systems and come in a wide variety of shapes and sizes. In an illustrative example, a transmission tower can range in height from 15 to 55 meters or more. Transmission towers 102 can be of various types including, e.g., suspension, terminal, tension, and transposition. In some embodiments, the utility grid 100 can include underground power lines in addition to or instead of transmission towers 102.

In some embodiments, the utility grid 100 includes a substation 104 or electrical substation 104 or substation transformer 104. A substation can be part of an electrical generation, transmission, and distribution system. In some embodiments, the substation 104 transform voltage from high to low, or the reverse, or performs any of several other functions to facilitate the distribution of electricity. In some embodiments, the utility grid 100 can include several substations 104 between the power plant 101 and the consumer electoral devices 119 with electric power flowing through them at different voltage levels.

The substations 104 can be remotely operated, supervised and controlled (e.g., via a supervisory control and data acquisition system or data processing system 150). A substation can include one or more transformers to change voltage levels between high transmission voltages and lower distribution voltages, or at the interconnection of two different transmission voltages.

The regulating transformer 106 can include: (1) a multi-tap autotransformer (single or three phase), which are used for distribution; or (2) on-load tap changer (three phase transformer), which can be integrated into a substation transformer 104 and used for both transmission and distribution. The illustrated system described herein can be implemented as either a single-phase or three-phase distribution system. The utility grid 100 can include an alternating current (AC) power distribution system and the term voltage can refer to an “RMS Voltage”, in some embodiments.

The utility grid 100 can include a distribution point 114 or distribution transformer 114, which can refer to an electric power distribution system. In some embodiments, the distribution point 114 can be a final or near final stage in the delivery of electric power. For example, the distribution point 114 can carry electricity from the transmission system (which can include one or more transmission towers 102) to individual consumers 119. In some embodiments, the distribution system can include the substations 104 and connect to the transmission system to lower the transmission voltage to medium voltage ranging between 2 kV and 35 kV with the use of transformers, for example. Primary distribution lines or circuit 112 carry this medium voltage power to distribution transformers located near the customer's premises 119. Distribution transformers can further lower the voltage to the utilization voltage of appliances and can feed several customers 119 through secondary distribution lines or circuits 116 at this voltage. Commercial and residential customers 119 can be connected to the secondary distribution lines through service drops. In some embodiments, customers demanding high load can be connected directly at the primary distribution level or the sub-transmission level.

The utility grid 100 can include or couple to one or more consumer sites 119. Consumer sites 119 can include, for example, a building, house, shopping mall, factory, office building, residential building, commercial building, stadium, movie theater, etc. The consumer sites 119 can be configured to receive electricity from the distribution point 114 via a power line (above ground or underground). A consumer site 119 can be coupled to the distribution point 114 via a power line. The consumer site 119 can be further coupled to a site meter 118a-n or advanced metering infrastructure (“AMI”). The site meter 118a-n can be associated with a controllable primary circuit segment 112. The association can be stored as a pointer, link, field, data record, or other indicator in a data file in a database.

The utility grid 100 can include site meters 118a-n or AMI. Site meters 118a-n can measure, collect, and analyze energy usage, and communicate with metering devices such as electricity meters, gas meters, heat meters, and water meters, either on request or on a schedule. Site meters 118a-n can include hardware, software, communications, consumer energy displays and controllers, customer associated systems, Meter Data Management (MDM) software, or supplier business systems. In some embodiments, the site meters 118a-n can obtain samples of electricity usage in real time or based on a time interval, and convey, transmit or otherwise provide the information. In some embodiments, the information collected by the site meter can be referred to as meter observations or metering observations and can include the samples of electricity usage. In some embodiments, the site meter 118a-n can convey the metering observations along with additional information such as a unique identifier of the site meter 118a-n, unique identifier of the consumer, a time stamp, date stamp, temperature reading, humidity reading, ambient temperature reading, etc. In some embodiments, each consumer site 119 (or electronic device) can include or be coupled to a corresponding site meter or monitoring device 118a-118n.

Monitoring devices 118a-118n can be coupled through communications media 122a-122n to voltage controller 108. Voltage controller 108 can compute (e.g., discrete-time, continuously or based on a time interval or responsive to a condition/event) values for electricity that facilitates regulating or controlling electricity supplied or provided via the utility grid. For example, the voltage controller 108 can compute estimated deviant voltage levels that the supplied electricity (e.g., supplied from power source 101) will not drop below or exceed as a result of varying electrical consumption by the one or more electrical devices 119. The deviant voltage levels can be computed based on a predetermined confidence level and the detected measurements. Voltage controller 108 can include a voltage signal processing circuit 126 that receives sampled signals from metering devices 118a-118n. Metering devices 118a-118n can process and sample the voltage signals such that the sampled voltage signals are sampled as a time series (e.g., uniform time series free of spectral aliases or non-uniform time series).

Voltage signal processing circuit 126 can receive signals via communications media 122a-n from metering devices 118a-n, process the signals, and feed them to voltage adjustment decision processor circuit 128. Although the term “circuit” is used in this description, the term is not meant to limit this disclosure to a particular type of hardware or design, and other terms known generally known such as the term “element”, “hardware”, “device” or “apparatus” could be used synonymously with or in place of term “circuit” and can perform the same function. For example, in some embodiments the functionality can be carried out using one or more digital processors, e.g., implementing one or more digital signal processing algorithms. Adjustment decision processor circuit 128 can determine a voltage location with respect to a defined decision boundary and set the tap position and settings in response to the determined location. For example, the adjustment decision processing circuit 128 in voltage controller 108 can compute a deviant voltage level that is used to adjust the voltage level output of electricity supplied to the electrical device. Thus, one of the multiple tap settings of regulating transformer 106 can be continuously selected by voltage controller 108 via regulator interface 110 to supply electricity to the one or more electrical devices based on the computed deviant voltage level. The voltage controller 108 can also receive information about voltage regulator transformer 106a or output tap settings 106b via the regulator interface 110. Regulator interface 110 can include a processor-controlled circuit for selecting one of the multiple tap settings in voltage regulating transformer 106 in response to an indication signal from voltage controller 108. As the computed deviant voltage level changes, other tap settings 106b (or settings) of regulating transformer 106a are selected by voltage controller 108 to change the voltage level of the electricity supplied to the one or more electrical devices 119.

The network 140 can be connected via wired or wireless links. Wired links can include Digital Subscriber Line (DSL), coaxial cable lines, or optical fiber lines. The wireless links can include BLUETOOTH, Wi-Fi, Worldwide Interoperability for Microwave Access (WiMAX), an infrared channel or satellite band. The wireless links can also include any cellular network standards used to communicate among mobile devices, including standards that qualify as 1G, 2G, 3G, or 4G. The network standards can qualify as one or more generation of mobile telecommunication standards by fulfilling a specification or standards such as the specifications maintained by International Telecommunication Union. The 3G standards, for example, can correspond to the International Mobile Telecommunications-2000 (IMT-2000) specification, and the 4G standards can correspond to the International Mobile Telecommunications Advanced (IMT-Advanced) specification. Examples of cellular network standards include AMPS, GSM, GPRS, UMTS, LTE, LTE Advanced, Mobile WiMAX, and WiMAX-Advanced. Cellular network standards can use various channel access methods e.g., FDMA, TDMA, CDMA, or SDMA. In some embodiments, different types of data can be transmitted via different links and standards. In other embodiments, the same types of data can be transmitted via different links and standards.

The network 140 can be any type and/or form of network. The geographical scope of the network 140 can vary widely and the network 140 can be a body area network (BAN), a personal area network (PAN), a local-area network (LAN), e.g., Intranet, a metropolitan area network (MAN), a wide area network (WAN), or the Internet. The topology of the network 140 can be of any form and can include, e.g., any of the following: point-to-point, bus, star, ring, mesh, or tree. The network 140 can be an overlay network which is virtual and sits on top of one or more layers of other networks 140. The network 140 can be of any such network topology as known to those ordinarily skilled in the art capable of supporting the operations described herein. The network 140 can utilize different techniques and layers or stacks of protocols, including, e.g., the Ethernet protocol, the internet protocol suite (TCP/IP), the ATM (Asynchronous Transfer Mode) technique, the SONET (Synchronous Optical Networking) protocol, or the SDH (Synchronous Digital Hierarchy) protocol. The TCP/IP internet protocol suite can include application layer, transport layer, internet layer (including, e.g., IPv6), or the link layer. The network 140 can be a type of a broadcast network, a telecommunications network, a data communication network, or a computer network.

One or more components, assets, or devices of utility grid 100 can communicate via network 140. The utility grid 100 can use one or more networks, such as public or private networks. The utility grid 100 can communicate or interface with a data processing system 150 designed and constructed to communicate, interface, or control the utility grid 100 via network 140. Each asset, device, or component of utility grid 100 can include one or more computing devices 400 or a portion of computing device 400 or some or all functionality of computing device 400.

The data processing system 150 can reside on a computing device of the utility grid 100, or on a computing device or server external from, or remote from the utility grid 100. The data processing system 150 can reside or execute in a cloud computing environment or distributed computing environment. The data processing system 150 can reside on or execute on multiple local computing devices located throughout the utility grid 100. For example, the utility grid 100 can include multiple local computing devices each configured with one or more components or functionality of the data processing system 150. In some cases, the data processing system 150 may be referred to as a server or a cloud computing device configured to process information received from one or more devices or components within the utility grid 100, among other environments in communication via the network 140.

Each of the components of the data processing system 150 can be implemented using hardware or a combination of software and hardware. Each component of the data processing system 150 can include logical circuitry (e.g., a central processing unit or CPU) that responds to and processes instructions fetched from a memory unit. Each component of the data processing system 150 can include or use a microprocessor or a multi-core processor. A multi-core processor can include two or more processing units on a single computing component. Each component of the data processing system 150 can be based on any of these processors, or any other processor capable of operating as described herein. Each processor can utilize instruction level parallelism, thread level parallelism, different levels of cache, etc. For example, the data processing system 150 can include at least one logic device such as a computing device or server having at least one processor to communicate via the network 140.

The components and elements of the data processing system 150 can be separate components, a single component, or part of the data processing system 150. For example, individual components or elements of the data processing system 150 can operate concurrently to perform at least one feature or function discussed herein. In another example, components of the data processing system 150 can execute individual instructions or tasks. The components of the data processing system 150 can be connected or communicatively coupled to one another. The connection between the various components of the data processing system 150 can be wired or wireless, or any combination thereof. Counterpart systems or components can be hosted on other computing devices.

The data processing system 150 can communicate with one or more metering devices 118 via the network 140. The data processing system 150 can obtain measurements from the one or more metering devices 118 within the utility grid 100. Each metering device 118 can measure an analog voltage waveform at high sampling rates in order to accurately resolve them in digitized samples. For example, the metering devices 118 can measure the (e.g., voltage) waveform at 10 kHz or higher. The metering device 118 (or other devices at the grid edge configured to measure the waveform, such as the one or more electronic devices 119) can be one of or a part of edge devices at the grid edge. In some cases, the data processing system 150 can be a part of the edge devices configured or equipped with computational power to carry out the various computations. By utilizing the digitized waveforms at high sampling rates or resolutions (e.g., capturing high-time-resolution voltage data by the metering devices 118), the data processing system 150 can perform computation on metering points to determine the characteristics of the high-resolution voltage waveforms, among other features of the voltage waveforms discussed herein.

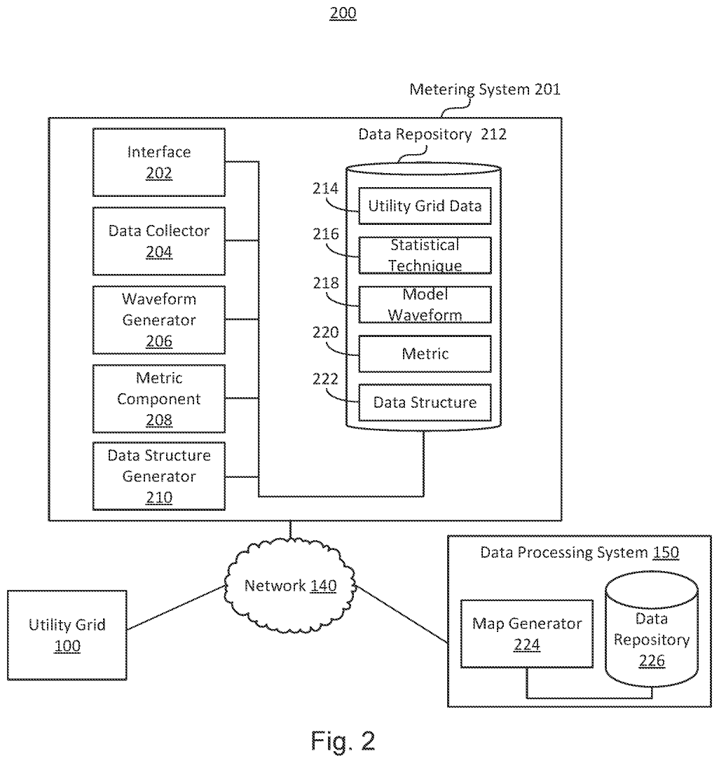

FIG. 2 illustrates a block diagram illustrating an example system to identify a location on a grid according to a voltage fingerprint. The system 200 can include, interface with, access, or otherwise communicate with at least one utility grid 100, at least one data processing system 150, and at least one metering system 201. The metering system 201 can include one or more components (e.g., one or more processors, memory, databases, interfaces, etc.) configured to perform features or functionalities discussed herein for managing the utility grid 100 or localization on the utility grid 100. The metering system 201 can include or correspond to one or more metering devices 118 located in the utility grid 100. In some cases, the metering system 201 can be a computing device local to or remote from the utility grid 100 or the data processing system 150. In some other cases, the metering system 201 can be a part of or perform one or more functionalities similar to the data processing system 150. The metering system 201 can transmit or receive data to or from other components (e.g., utility grid 100 or data processing system 150) of the system 200 via the network 140. The utility grid 100 and the network 140 can be referred to in conjunction with FIG. 1. The one or more devices, components, or systems (e.g., data processing system 150, metering system 201 (or metering devices 118), etc.) of the utility grid 100 or the system 200 can be composed of hardware, software, or a combination of hardware and software components.

The metering system 201 can include or correspond to at least one metering device 118, such as one of the metering devices 118 configured to perform one or more features (e.g., collect and process electricity characteristics) for localization on the utility grid 100. The metering system 201 can be located within the utility grid 100. For example, the metering system 201 can be positioned, installed, or provided at a location downstream from the substation 104 on the utility grid 100 that distributes electricity. The the metering system 201 being downstream from the substation 104 may refer to receiving power from the power source 101 via the substation 104, e.g., the substation 104 can be an intermediary between the power source 101 and the metering system 201. Other metering systems can be distributed or installed throughout the utility grid 100, configured to perform one or more features or functionalities similar to the metering system 201. In various cases, the metering systems (including the metering system 201) can correspond to or include edge devices within the utility grid 100.

The metering system 201 can receive and process data locally on the utility grid 100. In some cases, the metering system 201 can forward or delegate one or more features or functionalities to another computing device local to or remote from the utility grid 100. For instance, the metering system 201 can transmit data to the data processing system 150 executing in a cloud computing environment or distributed computing environment. In this case, the metering system 201 may perform a portion of the functionalities for processing information (e.g., electrical characteristics) local to the utility grid 100 and the data processing system 150 may perform another portion of the functionalities for processing the information (or processed data from the metering system 201).

The metering system 201 can include one or more components for localization within the utility grid 100 (e.g., electricity distribution grid), for instance, at least one interface 202, at least one data collector 204, at least one waveform generator 206, at least one metric component 208, at least one data structure generator 210, and at least one data repository 212. Each of the components (e.g., interface 202, data collector 204, waveform generator 206, metric component 208, data structure generator 210, or data repository 212) of the metering system 201 can be implemented using hardware or a combination of software and hardware. Each component of the metering system 201 can include logical circuitry (e.g., a central processing unit or CPU) that responds to and processes instructions fetched from a memory unit (e.g., memory 415 or storage device 425). Each component of the metering system 201 can include or use a microprocessor or a multi-core processor. A multi-core processor can include two or more processing units on a single computing component. Each component of the metering system 201 can be based on any of these processors, or any other processor capable of operating as described herein. Each processor can utilize instruction level parallelism, thread level parallelism, different levels of cache, etc. For example, the metering system 201 can include at least one logic device such as a computing device or server having at least one processor to communicate via the network 140.

The components and elements (e.g., interface 202, data collector 204, waveform generator 206, metric component 208, data structure generator 210, or data repository 212) of the metering system 201 can be separate components, a single component, or part of the metering system 201. For example, individual components or elements of the metering system 201 can operate concurrently to perform at least one feature or function discussed herein. In another example, components of the metering system 201 can execute individual instructions or tasks. In yet another example, the components of the metering system 201 can be a single component to perform one or more features or functions discussed herein. The components of the metering system 201 can be connected or communicatively coupled to one another, such as via the interface 202. The connection between the various components of the metering system 201 can be wired or wireless, or any combination thereof. Counterpart systems or components can be hosted on other computing devices.

The interface 202 can interface with the network 140, devices within the system 200 (e.g., data processing system 150 or utility grid 100), or components of the metering system 201. The interface 202 can include features and functionalities similar to the communication interface of one or more metering devices 118 to interface with the aforementioned components, such as in conjunction with FIG. 1. For example, the interface 202 can include standard telephone lines LAN or WAN links (e.g., 802.11, T1, T3, Gigabit Ethernet, Infiniband), broadband connections (e.g., ISDN, Frame Relay, ATM, Gigabit Ethernet, Ethernet-over-SONET, ADSL, VDSL, BPON, GPON, fiber optical including FiOS), wireless connections, or some combination of any or all of the above. Connections can be established using a variety of communication protocols (e.g., TCP/IP, Ethernet, ARCNET, SONET, SDH, Fiber Distributed Data Interface (FDDI), IEEE 802.11a/b/g/n/ac CDMA, GSM, WiMax and direct asynchronous connections). The interface 202 can include at least a built-in network adapter, network interface card, PCMCIA network card, EXPRESSCARD network card, card bus network adapter, wireless network adapter, USB network adapter, modem, or any other device suitable for interfacing one or more devices within the system 200 to any type of network capable of communication. The interface 202 can communicate with one or more aforementioned components to receive data from at least one of the utility grid 100 or the data processing system 150, such as data representative of electricity distribution to individual metering devices 118 within the utility grid 100 or instructions from the data processing system 150.

The data collector 204 can obtain or collect electrical data within the utility grid 100. The data collector 204 can receive electrical data including data samples of an electrical waveform corresponding to electricity (e.g., electrical signals) distributed at the location of the metering system 201 on the utility grid 100. In various cases, the data collector 204 can receive relatively high-resolution data, such as at least 1 kHz of voltage data. For simplicity and for purposes of examples herein, the electrical data discussed herein can be voltage data, although other types of electrical data can be obtained, such as power or current electrical information.

To obtain the electrical data, the data collector 204 can receive measurements of the electrical signals from the interface 202. For example, the interface 202 of the metering system 201 can include one or more sensors (e.g., voltage sensors). In some cases, the one or more sensors can be communicatively coupled with the metering system 201 or one or more components of the metering system 201. The one or more sensors can measure the voltage waveform of electricity from the utility grid 100. Responsive to measuring the voltage waveform, the one or more sensors can provide the data samples to the data collector 204. The data collector 204 can receive the data samples from the one or more sensors including the voltage waveform corresponding to or indicating the electricity at the location of the metering system 201. The data samples can include raw voltage information or data measured by the one or more sensors.

In some other cases, the one or more sensors may be remote from or external to the metering system 201. For example, the one or more sensors can be a part of another (intermediary) device operating at the location of the metering system 201. In this case, the one or more sensors can measure the voltage (e.g., voltage waveform) from the utility grid 100, recorded by the intermediary device. Subsequently, the intermediary device can generate data samples including the voltage waveform. In this case, the data collector 204 can receive the data samples from the one or more sensors as part of another device, for example.

In some aspects, the data collector 204 can include the one or more sensors, such that the data collector 204 can perform the measurements to obtain the voltage waveform data. The data collector 204 can continuously, periodically, or intermittently measure the voltage waveform. The data collector 204 may perform the measurement or obtain the voltage waveform data for predetermined time intervals, such as 1 minute, 5 minutes, 15 minutes, etc. The data collector 204 can store the collected electrical information in the data repository 212. The data collector 204 may retrieve the collected data from the data repository 212.

The waveform generator 206 can generate a model waveform based on or according to at least one of a sinusoidal waveform or the voltage waveform obtained by the data collector 204. The model waveform can include or represent an ideal sinusoidal waveform (e.g., ideal voltage waveform, such as corresponding to y=a*sin(bx)), which can be used for fitting to or adapting for the measured voltage waveform. For example, the waveform generator 206 can break the voltage waveform (e.g., waveform data) into multiple time windows. In some cases, the time windows can be uniform, including the same predetermined time interval, such as 1 second, 5 seconds, 30 seconds, 1 minute, etc. The metrics collected for each time window can be uniform as well; e.g., each time window can have a uniform set of metrics collected or generated. In some other cases, one or more time windows may not be uniform with other time windows. In this case, certain time windows may include different time intervals. The waveform generator 206 can fit a sinusoidal waveform (e.g., ideal sinusoidal waveform) to the voltage waveform to generate the model waveform by performing perform one or more suitable statistical techniques. The waveform generator 206 can perform the fitting for each time window of the voltage waveform. The waveform generator 206 can access the statistical techniques stored in the data repository 212 or from remote data storage.

Examples of the statistical techniques can include, but are not limited to, fit root mean square error (RMSE) mean, fit RMSE standard deviation, fit mean absolute error (MAE), fit amplitude mean root mean square (RMS), fit amplitude standard deviation, fit frequency mean, fit frequency standard deviation, standard deviation, skewness, kurtosis, sum, sum log, largest harmonic, largest harmonic value, largest harmonic phase shift, second largest harmonic, second largest harmonic value, second largest harmonic phase shift, total harmonic distortion mean, total harmonic distortion mean, total harmonic distortion standard deviation, total harmonic distortion 90^{th} quantile, total harmonic distortion 80^{th} quantile, total harmonic distortion 10^{th} quantile, etc.

Performing the fit RMSE mean can involve computing the mean of the RMSEs between the (ideal) sinusoidal waveform fit to the measured voltage waveform and the measured voltage waveform. A relatively lower value generated using the fit RMSE mean statistical technique can indicate a relatively higher power quality in the model waveform. The power quality can represent the degree to which the voltage waveform conforms to the specification or satisfy a desirable result. Performing the fit RMSE standard deviation can involve computing the standard deviation of the RMSEs between an ideal sinusoidal waveform fit to the measured voltage waveform and the measured voltage waveform. The fit RMSE standard deviation (e.g., metric) can be used to measure the voltage stiffness (e.g., a measure of the relative resistance (impedance) of the source compared to the load). Relatively lower values generated using the fit RMSE standard deviation can indicate a relatively more stable waveform and relatively higher values can indicate anomalous electrical behavior or characteristics.

Performing the fit MAE can involve computing the MAE between an ideal sinusoidal waveform fit to the measured voltage waveform and the measured voltage waveform. A relatively lower value generated using the fit MAE can indicate a relatively more consistent waveform compared to the ideal sinusoidal waveform. Performing the fit amplitude mean RMS can involve computing the mean amplitude of an ideal sinusoidal waveform fit to the measured voltage waveform. The value can be scaled by the square root of 2 (e.g., √2) to output the RMS. The RMS value (e.g., scaled value) can be compared to a nominal value of 120 volts, among other voltages, as a measure of power quality.

Performing the fit amplitude standard deviation can involve the standard deviation of the amplitude of an ideal sinusoidal waveform fit to the measured voltage waveform. The fit amplitude standard deviation (e.g., metric) can measure the voltage stiffness. A relatively lower value generated by the fit amplitude standard deviation can indicate a relatively more consistent voltage. Performing the fit frequency mean can involve the mean frequency of an ideal sinusoidal waveform fit to the measured voltage waveform. The value (e.g., the mean frequency) generated using the fit frequency mean can be compared to the nominal value of 60 Hz, among other frequencies, as a measure of power quality.

Performing the fit frequency standard deviation can involve the standard deviation in the frequency of an ideal sinusoidal waveform fit to the measured voltage waveform. The generated output using the fit frequency standard deviation can measure the voltage stiffness in the frequency domain, for example. According to at least one of the above statistical techniques, the waveform generator 206 can fit or determine the difference between the (ideal) sinusoidal waveform to the measured voltage waveform to generate the model waveform (or at least one of the metrics). In various cases, the statistical techniques discussed herein can be used to determine one or more metrics for the voltage waveform.

Skewness can refer to the measurement of symmetry (or lack of symmetry) of the voltage waveform (e.g., compared to the ideal sinusoidal waveform). Kurtosis can refer to a measure of whether the voltage waveform data are heavy-tailed or light-tailed relative to a normal distribution (e.g., of the ideal sinusoidal waveform). The sum between two waveforms can result in the amplitude (e.g., peak or RMS), such as between the voltage waveform data and the ideal sinusoidal waveform data. The sum log can correspond to a log (e.g., record or collection of) multiple sums between two waveforms.

The largest harmonic can correspond to an integer number (e.g., in multiple of the fundamental frequency, such as 60 Hz) of the harmonic with the largest magnitude. The largest harmonic value can correspond to the magnitude of the largest harmonic. The largest harmonic phase shift can correspond to the phase shift (e.g., lagging or leading) between the phase of the voltage waveform and the current waveform at the frequency of the largest harmonic. The second largest harmonic can correspond to an integer number (e.g., in multiple of the fundamental frequency) of the harmonic with the second largest magnitude. The second largest harmonic value can correspond to the magnitude of the second largest harmonic. The second largest harmonic phase shift can correspond to the phase shift (e.g., lagging or leading) between the phase of the voltage waveform and the current waveform at the frequency of the second largest harmonic.

The total harmonic distortion mean can correspond to the mean of the total harmonic distortion (THD) computed for a subset of windows within a time interval (e.g., a larger window) associated with the statistics being recorded or reported, such as applied or used for one or more statistical techniques herein. The THD can be calculated as or correspond to the first equation using odd harmonics. The total harmonic distortion mean can correspond to the median of the total harmonic distortion. The total harmonic distortion standard deviation can correspond to the standard deviation of the total harmonic distortion. The total harmonic distortion 90^{th} quantile can correspond to the 90^{th} quantile of the total harmonic distortion. The total harmonic distortion 80^{th} quantile can correspond to the 80th quantile of the total harmonic distortion. The total harmonic distortion 10^{th} quantile can correspond to the 10th quantile of the total harmonic distortion.

The metric component 208 can determine one or more metrics (e.g., sometimes referred to as statistics or tables) for the voltage waveform over a time interval. The time interval can be predetermined according to the setting of the metering system 201 or the configuration of the data processing system 150 configured to determine the topology relationship between the metering systems within the utility grid 100. The metric component 208 can receive the voltage waveform measured or received by the data collector 204. The metric component 208 may obtain the model waveform generated by the waveform generator 206. In some cases, the metric component 208 can obtain multiple time windows of the voltage waveform over the time interval.

The metric component 208 can determine the metrics for the time windows over the time interval. For example, the metric component 208 can compute a set of metrics for the voltage waveform over the time intervals using at least one of the statistical techniques, such as fit RMSE mean, fit RMSE standard deviation, fit MAE, fit amplitude mean RMS, fit amplitude standard deviation, fit frequency mean, fit frequency standard deviation, etc. In this example, the metric component 208 can determine the set of metrics (e.g., first set of metrics) by calculating the various statistics on the voltage waveform itself. The metric component 208 can compute one value for a given time window (e.g., one output from a one-second window, one output from a 5 seconds window, or other time duration windows). In this case, each computed value associated with a window can represent one of the metrics over the time interval. The metric component 208 can iteratively compute the values for the remaining time windows using the at least one statistical technique to determine the set of metrics.

In some cases, the metric component 208 can determine multiple sets of metrics using other types of statistical metrics. For example, the metric component 208 can determine a first set of metrics for the voltage waveform using a first type of statistical technique, a second set of metrics using a second type of statistical technique, a third set of metrics using a third type of statistical technique, etc. In some configurations, the metric component 208 may combine or aggregate the values between at least two sets of metrics. For example, the metric component 208 can compute a mean, average, or other types of aggregation, between values of a first set of metrics and a second set of metrics to output values for a third set of metrics.

In some aspects, the metric component 208 may determine a set of metrics (e.g., second set of metrics) for the voltage waveform over the time interval based on the difference between the (measured) voltage waveform and the model waveform. In this case, the model waveform may correspond to the ideal sinusoidal waveform. For example, the metric component 208 can determine each of the metrics based on an error metric (e.g., fit RMSE mean, fit RMSE standard deviation, or fit MAE) computed between the voltage waveform and the model waveform fit based on a sinusoidal waveform to the voltage waveform (e.g., model waveform corresponding to the voltage waveform fit to the ideal sinusoidal waveform).

In another example, the metric component 208 can generate the set of metrics based on at least one of a mean amplitude (e.g., fit amplitude mean RMS or fit amplitude standard deviation) or a mean frequency (e.g., fit frequency mean or fit frequency standard deviation) of the model waveform fit based on a sinusoidal waveform to the voltage waveform. In this example, the metric component 208 can fit the ideal sinusoidal waveform to the voltage waveform using at least one of the statistical techniques, such as the fit amplitude or fit frequency statistical technique(s) to generate the set of metrics.

In some cases, the metric component 208 may determine or compute this set of metrics (e.g., second set of metrics according to the difference between the voltage waveform and the model waveform) if the statistical measurements are the same between two locations that are, for instance, electrically or spatially far apart (e.g., the mean of the voltage may be similar at many locations on the utility grid 100). For example, fitting the model waveform (e.g., including the ideal sinusoidal waveform) to the measured voltage waveform can provide a unique, yet global, (e.g., sine wave) template, thereby providing further distinctions between two locations additionally or alternatively to the first set of metrics.

The number of metrics generated by the metric component 208 can be based on the window size and the time interval. For example, each metric can include or correspond to a value determined for a window within the time interval. If the window is 1 second and the time interval is 15 minutes, the total number of metrics is 60 (e.g., values from the 60 seconds)×15 (e.g., minutes of the time interval)=900 metrics for a set of metrics. The metric component 208 can generate another set of metrics according to a different statistical technique or another difference between the voltage waveform and the model waveform, for example.

Subsequent to determining or generating the metrics, the metric component 208 can provide the metrics for the data structure generator 210. The metrics (e.g., in each set of metrics) can indicate characteristics of the voltage waveform measured by the data collector 204. By generating the metrics from the waveform data (e.g., voltage waveform, model waveform, or sinusoidal waveform), the metric component 208 can reduce data size or network resources (e.g., distilled or filtered information) when providing to the data processing system 150 or other remote computing devices within the network 140 for topology determination.

Additionally or alternatively, the metric component 208 can determine or perform another set of metrics or computations to fit the voltage waveforms or RMS statistics to a user-defined model (e.g., an autoregressive moving average model or other types of models). In some cases, the voltage waveforms or RMS statistics can be used for training or executing a machine learning model (e.g., an autoencoder, among other types of machine learning models), for instance, to distinguish or determine the location(s) within the utility grid 100, such as by the data processing system 150.

The data structure generator 210 can construct or generate one or more data structures including at least one of the various metrics and information associated with the metering system 201. The data structure generator 210 can generate the one or more data structures including an aggregation of information/data collected, measured, or generated by other components of the metering system 201. For example, after obtaining one or more sets of metrics, such as from the one or more components of the metering system 201 or obtained from the data repository 212, the data structure generator 210 can generate a data structure including a first set of metrics determined via the statistical technique, a second set of metrics determined based on the difference between the voltage waveform and the model waveform, and other sets of metrics determined by the waveform generator 206. The data structure generator 210 can include an identifier representing the metering system 201 (e.g., meter identifier (ID)). The metrics can be associated with the identifier. In some cases, the identifier can indicate a geographical location of the metering system 201, for instance, recorded by a grid operator during installation or maintenance of the metering system 201. The data structure generator 210 can store the constructed data structure in the data repository 212. The identifier can be used to search for the constructed data structure in the data repository 212 (e.g., the identifier used as a search key in a look-up table).

After generating the data structure, the metering system 201 can provide or upload the data structure to the data processing system 150 for processing (e.g., to evaluate a performance of the utility grid 100). The identifiers from the metering systems of the utility grid 100 can be used by the data processing system 150 for storing the data structure from the metering systems, searching, or performing a look-up in a remote data repository (e.g., data repository 226) for information related to the respective metering systems, such as the data structures of the metering systems, or for associating indications of metering system locations. For instance, the metering system 201 can provide the data structure to the data processing system 150 to be stored in the data repository 226 according to the identifier of the metering system 201, or other metering systems. Once the topology of the metering systems is determined, thereby the locations of the metering systems, an indication of the location (e.g., location indicator) of each metering system or a secondary transformer for each metering system can be stored by the data processing system 150 in association with its identifier. In such cases, the data processing system 150 may store a first identifier for a first location of a first metering system, a second identifier for a second location of a second metering system, a third identifier for a third location of a third metering system, etc. In some cases, the identifiers can be used to identify the location of the respective metering systems historically recorded by, for instance, the grid operator.

In various aspects, the data structure generator 210 can construct the data structure by aggregating each set of metrics. The data structure generator 210 can aggregate the metrics by combining multiple metrics sequentially, such as according to the timestamps associated with the metrics. For example, for each set of metrics, the data structure generator 210 can combine or order the metrics sequentially according to the timestamps associated with the metrics. In another example, the data structure generator 210 can divide the metrics in each set of metrics into different subsets according to the timestamp of the metrics. Each subset of metrics can include a predetermined number of metrics. In this example, the data structure generator 210 can aggregate the metrics (or values) of each subset to output a value for each subset of metrics. For instance, the set of metrics can include 100 metrics. If the subset of metrics is configured as 10, the data structure generator 210 can split the metrics into 10 subsets. The data structure generator 210 can aggregate each of the 10 subsets, thereby outputting 10 respective aggregated values for the 10 subsets. The aggregate value can be one of the average, mean, median, mode, highest, or lowest value of the metrics in the subset, according to the configuration of the metering system 201 (e.g., instructions from the data processing system 150 to various metering systems). In such cases, the data structure generator 210 can reduce the size of the data structure (e.g., output one value for each subset of 10 metrics), thereby reducing network resources during data transmission to the data processing system 150.

In some cases, the data structure generator 210 can generate multiple data structures for the metering system 201 according to different time intervals. For example, the data structure generator 210 can generate a first data structure with first values for the first set of metrics over a first time interval of the voltage waveform, and first values for the second set of metrics over the first time interval of the voltage waveform (e.g., each data structure including multiple sets of metrics). The data structure generator 210 can generate a second data structure with second values for the first set of metrics over a second time interval of the voltage waveform, and second values for the second set of metrics over the second time interval of the voltage waveform. The data structure generator 210 can generate a third data structure with third values for the first set of metrics over a third time interval of the voltage waveform, and third values for the second set of metrics over the third time interval of the voltage waveform. After generating the data structures, the data structure generator 210 can provide the data structures (e.g., or a single data structure including the first to third data structures) to the data processing system 150 over a batch upload process. The batch upload process can refer to accumulating data at the metering system 201 (e.g., for multiple time intervals) before uploading to the data processing system 150.

In some cases, the metering system 201 may not transmit the constructed data structure to the data processing system 150 until an upload threshold is satisfied. The upload threshold can include at least one of a minimum, a maximum, or a range of the size for data transmission, the number of data structures to be uploaded, or the number of metering systems queuing to upload the data structure(s) (e.g., metering systems can communicate with each other), etc. The metering system 201 (or other metering systems) may upload the data structure(s) responsive to satisfying the upload threshold. In some cases, if the metering system 201 uploads the data structure without satisfying the upload threshold, the data processing system 150 may reject the transmission or drop the data packet. In some aspects, the metering system 201 can upload the data structure responsive to the construction by the data structure generator 210. In some configurations, the metering system 201 can receive data structures constructed by other metering systems. In such cases, the metering system 201 (e.g., a single metering system) can upload the data structures from multiple metering systems to the data processing system 150 as part of the same or different batch upload process.

Multiple metering systems can perform the uploading process to the data processing system 150 individually. For example, a second metering system can reside at a second location on the utility grid 100 and a third metering system can reside at a third location on the utility grid 100. The second metering system can generate a second data structure with values for the first set of metrics over the time interval of a second voltage waveform (e.g., similar time interval and statistical technique used by the metering system 201 or a first metering system), and values for the second set of metrics over the time interval of the second voltage waveform (e.g., similar technique performed for obtaining the values for the second metrics as the metering system 201). The second metering system can provide the second data structure to the data processing system 150. The third metering system can generate a third data structure with values for the first set of metrics over the time interval of a third voltage waveform, and values for the second set of metrics over the time interval of the third voltage waveform. The third metering system can provide the third data structure to the data processing system.

In various cases, the metering systems (e.g., metering system 201, second metering system, and third metering system) can provide the data structures (e.g., data structure from the metering system 201, second data structure, and third data structure) to the data processing system 150 to be evaluated simultaneously. In such cases, these metering systems may provide their constructed data structures at approximately the same time. For example, the metering systems can communicate with each other to upload the data structures at a certain time period. In another example, one of the metering systems can obtain the data structures of other metering systems to perform the batch upload process. In yet another example, the metering systems within the utility grid 100 can be configured by the data processing system 150 (or other administrator devices) to perform the upload process at predefined time periods, such as hourly, daily, weekly, etc. In some other cases, the metering systems can send the data structures at different times, such that the data processing system 150 can associate the different data structures according to the timestamp included in each data structure.

The metering system 201 can include the data repository 212 to store information or data collected, measured, obtained, or otherwise received as discussed herein. The data repository 212 may be referred to as a data storage, database, memory device, etc. The data repository 212 can include at least a utility grid data storage 214, a statistical technique storage 216, a model waveform storage 218, a metric storage 220, and a data structure storage 222. The data repository 212 can include other types of storage to store information for evaluating the performance of the utility grid 100 or localization within the utility grid 100. In some cases, information stored in the data repository 212 can be uploaded to or synced with the data repository 226 of the data processing system 150, among other cloud storage devices, or downloaded to the data repository 212 for processing. In some other cases, the information stored in the data repository 212 may be local to the metering system 201. The data repository 212 can be accessed by one or more components (e.g., data collector 204, waveform generator 206, metric component 208, or data structure generator 210) of the metering system 201, or at least one external or remote device, such as other metering systems within the utility grid 100, the data processing system 150, etc.

The utility grid data storage 214 can include, store, or maintain information related to the utility grid 100 obtained, measured, or detected by the metering system 201 (e.g., interface 202 or data collector 204). For example, the utility grid data storage 214 can store electrical data received or measured by the data collector 204. The electrical data can include the voltage waveform measured by the one or more sensors (e.g., voltage sensors) of the metering system 201. In some cases, the utility grid data storage 214 can include the identifier of the metering system 201, for instance, to be provided to the data processing system 150 during data transmission.

The statistical technique storage 216 can include, store, or maintain the statistical techniques to be utilized by at least one of the waveform generator 206 or the metric component 208. For example, the statistical technique storage 216 can store the statistical techniques including, but are not limited to, fit root mean square error (RMSE) mean, fit RMSE standard deviation, fit mean absolute error (MAE), fit amplitude mean root mean square (RMS), fit amplitude standard deviation, fit frequency mean, fit frequency standard deviation, standard deviation, skewness, kurtosis, sum, sum log, largest harmonic, largest harmonic value, largest harmonic phase shift, second largest harmonic, second largest harmonic value, second largest harmonic phase shift, total harmonic distortion mean, total harmonic distortion mean, total harmonic distortion standard deviation, total harmonic distortion 90^{th} quantile, total harmonic distortion 80^{th} quantile, total harmonic distortion 10^{th} quantile, etc. The statistical technique storage 216 can be accessed by the one or more components of the metering system 201 to obtain and utilize the statistical techniques. In some cases, the statistical technique storage 216 can be accessed by the one or more components of the metering system 201 to add, remove, or update the statistical techniques.

The model waveform storage 218 can include, store, or maintain the model waveform generated by the waveform generator 206. The model waveform storage 218 may be accessed by the one or more components of the metering system 201, such as the waveform generator 206 or the metric component 208. In some cases, the model waveform storage 218 can include, store, or maintain the ideal sinusoidal waveform used for generating the model waveform. The model waveform storage 218 may store multiple ideal sinusoidal waveforms. For example, each ideal sinusoidal waveform can be associated with a predetermined magnitude and frequency. The model waveform storage 218 can be accessed by the waveform generator 206 or the metric component 208 for comparison or differentiation between the ideal sinusoidal waveform and the measured voltage waveform. In some aspects, the model waveform storage 218 can store a timestamp for each model waveform generated by the waveform generator 206. In some cases, the model waveform can correspond to the ideal sinusoidal waveform for differentiation with the measured voltage waveform.

The metric storage 220 can include, store, or maintain metrics or sets of metrics determined by the metric component 208. The metric storage 220 can receive new or additional metrics from the metric component 208. The metric storage 220 can be accessed by the data structure generator 210 for generating the data structure using the metrics. The metric storage 220 can store a timestamp associated with each metric. For example, the metric storage 220 can store a timestamp indicating the time period when the metric is determined by the metric component 208. In another example, the metric storage 220 can store a timestamp indicating the time period when the waveforms (e.g., voltage waveform, sinusoidal waveform, or model waveform) used by the metric component 208 are received, measured, or generated by the one or more components of the metering system 201. In this example, the timestamp can represent the start time, end time, or other time instances associated with each window within the time interval for the voltage waveform. The metric can include or correspond to a value determined using the statistical technique on the voltage waveform. In some cases, the metric can include or correspond to a value determined using multiple statistical techniques (e.g., performed concurrently or simultaneously) on the voltage waveform.

The data structure storage 222 can include, store, or maintain data structures constructed or generated by the data structure generator 210. Each data structure stored in the data structure storage 222 can include one or more metrics determined for the voltage waveform over a respective time interval. In some cases, each data structure stored in the data structure storage 222 can include multiple data structures associated with respective time intervals. For example, the data structure storage 222 can store a data structure including a first data structure associated with a first time interval, a second data structure associated with a second time interval, a third data structure associated with a third time interval, etc. The data structure storage 222 can store a timestamp associated with when the data structure is constructed, when at least one metric used to construct the data structure is determined, or when the waveform(s) used to determine the metric is obtained or measured. The data structure storage 222 can store the identifier of the metering system 201 for each data structure. The data structure storage 222 can store other types of information to be provided to the data processing system 150, for instance, during (or outside of) the batch upload process. As discussed herein, other types of data received, transmitted, or generated by one or more components of the metering system 201 can be stored in the data repository 212.

The data processing system 150 can be remote from the utility grid 100 and the metering systems. The data processing system 150 can receive data structures (e.g., sets of metrics) from the metering systems, delivered via the batch upload process. By having the metering systems transmit the sets of metrics instead of the high-resolution information (e.g., waveform data recorded at a predefined resolution), the communication bandwidth or network resources consumed the data processing system 150 and multiple metering systems 201 (or metering devices 118) can be reduced or maintained within a desired bandwidth threshold.

The data processing system 150 can include one or more components for evaluating the performance of the utility grid 100, determining the topological relationship between the metering systems within the utility grid 100, or localization of the metering systems, among other functionalities discussed herein, such as according to the electrical characteristic (e.g., voltage fingerprint) captured by the metering systems. The one or more components of the data processing system 150 can include, for instance, at least one map generator 224 and at least one data repository 226. The data repository 226 may be referred to as a memory device of the data processing system 150 or a remote database relative to the metering systems. Each of the components (e.g., map generator 224 or data repository 226) of the data processing system 150 can be implemented using hardware or a combination of software and hardware. In various cases, the data processing system 150 can include other components to perform the features or functionalities discussed herein.

The data processing system 150 can receive the data transmission from the metering system 201, among other metering systems within the utility grid 100. The data transmission can include the one or more data structures constructed from the metering systems. The data transmission can include the identifiers of the respective metering systems. The data processing system 150 can receive the data structures from the metering systems as part of the batch upload process to reduce the network resource or bandwidth consumption, or minimize network traffic. The data processing system 150 or metering system 201 can initiate or perform the batch upload process at a time selected to balance network bandwidth consumption by other metering systems 201 on the utility grid. For example, different metering systems 201 can stagger when a batch upload process begins so that not all metering systems 201 on the utility grid are performing a batch upload at the same time, thereby balancing the network bandwidth utilization and reducing network latency, delay, or bit error rates.

In some cases, the data processing system 150 can receive additional or alternative information from the metering systems (e.g., other than the data structures and the identifiers of the metering systems) for processing. For example, certain features or functionalities of the one or more metering systems may be delegated to the data processing system 150, such as waveform generation, metric determination, or data structure construction. Depending on the delegated features, the data processing system 150 can receive suitable information from the metering systems, such as the electrical data or voltage waveforms, the model waveforms, or the metrics associated with the respective metering systems.

The data processing system 150 can store the received data from the metering systems in the data repository 226. The data repository 226 can store the data uploaded by the metering systems or other computing devices within the network 140. The data repository 226 can include, store, or maintain a table including indexes of identifiers for the metering systems of the utility grid 100. The data repository 226 can store information related to each metering system by associating or linking the information to the respective identifier. For example, the data repository 226 can perform a look-up in the table of identifiers using the identifier received from the metering system 201. Responsive to performing the look-up, the data repository 226 can provide the requested information to the one or more components of the data processing system 150, such as providing an indication of the location of the metering system 201 to the map generator 224. In some cases, the data repository 226 can store a topological relationship (e.g., an identifier or indication of a secondary transformer supplying power to the metering system 201) determined by the map generator 224, such as by associating the topological relationship with one or more respective identifiers of metering systems.

The map generator 224 can obtain the data structures from the metering systems 201 or the data repository 226. The map generator 224 can determine the topological relationship between multiple metering systems. The topological relationship can include or refer to the grouping of metering systems, such as a group of metering systems electrically coupled or connected to the same secondary transformer. A topological relationship can refer to or include a type of connectivity, such as series or parallel connection. The topological relationship can refer to or indicate a hub and spoke-connected grid or a mesh-connected grid. In some cases, to determine a location or topological relationship, the data processing system 150 can receive and process one or more data structures from one or more metering systems 201. For example, to facilitate triangulation, the map generator 224 can receive and process three data structures from each of three metering systems 201. The data structure can comprise a vector of values or metrics, including, for example, an identifier of the metering system 201, time stamps, and values of metrics.

For example, the map generator 224 can obtain the data structures (e.g., first to third data structures) from a first metering system (e.g., metering system 201), the second metering system, and a third metering system. The map generator 224 can identify the locations of these metering systems to determine whether they are within a predetermined distance from each other, such as within 150 feet, 200 feet, etc. The map generator 224 can disregard metering systems that are further than the predetermined distance from each other. The map generator 224 can analyze the metrics of the data structures from the metering systems within the predetermined distance from each other. The map generator 224 can determine the electrical characteristics (e.g., voltage fingerprint) at one or more time intervals for each data structure. The map generator 224 can compare the voltage fingerprints between data structures from different metering systems at similar time intervals. Depending on the similarities or differences between the voltage fingerprints, the map generator 224 can determine whether the metering systems are coupled to the same transformer (e.g., secondary transformer). Similar voltage fingerprints can indicate or reflect that the metering systems (within the predetermined distance) are receiving electricity from the same secondary transformer. Differing voltage fingerprints (e.g., from multiple time intervals) can indicate that one or more metering systems are receiving electricity from at least one other secondary transformer compared to other metering systems. Hence, the map generator 224 can determine the topological relationship (e.g., groupings) between the metering systems according to the data structures.

In some configurations, the data processing system 150 can determine the location of metering systems within the utility grid 100 according to the provided data structures (e.g., metrics determined by the metering systems). The measurements or statistics of the voltage from the metering systems (e.g., metering devices 118 or edge devices) can facilitate precise characterization of the location(s) on the utility grid 100 according to or by using the voltage statistics. For example, the data processing system 150 can compute or identify the characteristics (e.g., fluctuations, increases, decreases, delays, among other patterns) in the behavior of the voltage over time (e.g., sometimes referred to as voltage characteristics), such as according to the sets of metrics from individual metering systems. The data processing system 150 can use the information for data-driven electrical topology estimation, circuit switching determination, power flow operation and planning, or power quality analysis, among other features or evaluations of performance of the utility grid 100. The statistics (e.g., metrics) can support or be used for robust correlation between measurement locations.

In some configurations, the data processing system 150 can use the voltage characteristics to compute the dependency measures between locations of the metering devices 118. The dependency measure can include a measurement (e.g., metric or value) indicating or representing a level of interdependency between at least two metering devices 118 or between at least one metering device 118 to another component within the utility grid 100 (e.g., secondary transformer providing electricity to multiple metering devices 118). For example, a relatively greater level of interdependency (e.g., value of dependency measure) can represent relatively greater similarities between voltage characteristics between metering devices 118 or between at least one metering device 118 and another component within the utility grid 100. In contrast, a relatively lower level of interdependency can represent relatively fewer similarities between voltage characteristics between metering devices 118 or between at least one metering device 118 and another component within the utility grid 100. In further examples, the data processing system 150 can compare the dependency measures between metering devices 118 to determine a first location of a first metering device relative to a second location of a second metering device, such as based on similarities or differences between the respective dependency measures. In this example, the similarities or differences between the dependency measures of the metering devices 118 may be based on the component (e.g., upstream component) of the utility grid 100 supplying electricity to the respective metering devices 118. The upstream component of the metering device 118 can refer to any intermediate component between the metering device 118 and the power source 101, for example. In some cases, similar dependency measures can be computed for metering devices 118 associated with the same upstream component. In some other cases, different dependency measures can be computed for metering devices 118 associated with different upstream components. In another example, the data processing system 150 can compare the dependency measures between at least one metering device 118 and a secondary transformer to determine the location of the metering device 118 relative to the location of the secondary transformer.

In some cases, the data processing system 150 or the metering systems can be in communication with a global positioning system (GPS). The GPS can be utilized to synchronize the measurements (e.g., from the metering systems or metering devices 118) to within or under a predefined time (e.g., 0.0001 seconds or greater time resolution). The data processing system 150 may transmit a signal to synchronize the metering systems according to information from the GPS. By synchronizing the measurements, the data processing system 150 can use the synchronized measurement of the metering systems to determine the causation of events.

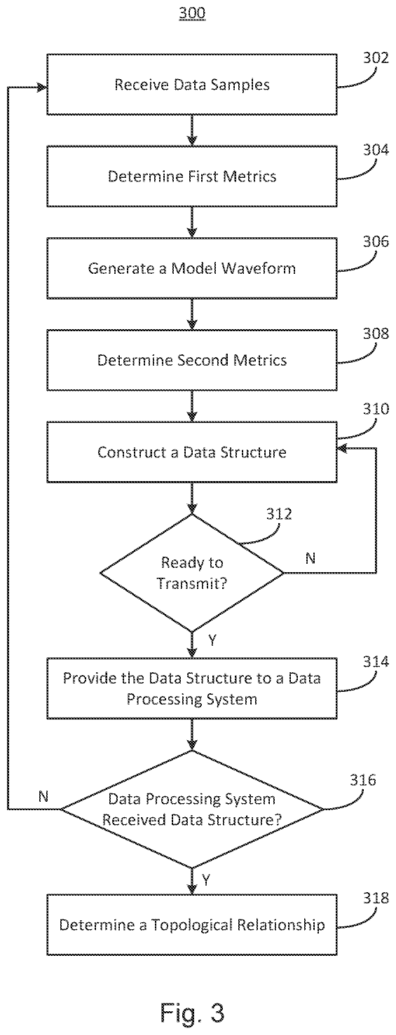

FIG. 3 depicts an example flow diagram of a method 300 for localization according to meter voltage fingerprint. The example method 300 can be executed, performed, or otherwise carried out by one or more components of the utility grid 100 (e.g., computing device, metering devices 118, data processing system 150, etc.), the system 200 (e.g., data processing system 150, metering system 201, etc.), or computing device 400, etc. The method 300 can include receiving data samples, at ACT 302. At ACT 304, the method 300 can include determining a first plurality of metrics. At ACT 306, the method 300 can include generating a model waveform. At ACT 308, the method 300 can include determining a second plurality of metrics. At ACT 310, the method 300 can include constructing a data structure. At ACT 312, the method 300 can include determining whether ready to transmit. At ACT 314, the method 300 can include providing the data structure to a data processing system. At ACT 316, the method 300 can include determining whether the data processing system received the data structure. At ACT 318, the method 300 can include determining a topological relationship.

At ACT 302, a metering system (e.g., metering device) at a location downstream from a substation on a utility grid that distributes electricity can receive data samples of a voltage waveform corresponding to the electricity distributed at the location. The metering system can receive the data samples from the utility grid distributing electricity to various edge devices (e.g., metering systems or metering devices). The metering system can store and retrieve the data samples from a local data repository.

In some cases, the metering system can receive the data samples from one or more sensors performing measurements of the voltage waveform. For example, the metering system can include or be coupled to one or more sensors (e.g., voltage sensors). The one or more sensors can be a part of or an external device from the metering system. The one or more sensors can measure the voltage waveform to generate or provide the data samples. Responsive to measuring the voltage waveform, the metering system can obtain the data samples.

At ACT 304, the metering system can determine the first plurality of metrics (e.g., a first set of metrics) for the voltage waveform over a time interval via a statistical technique. For example, the metering system can perform at least one statistical technique on the voltage waveform within a time window of the time interval. The metering system can determine the amplitude, frequency, period, speed, interference, RMS, peaks, standard deviations between cycles, kurtosis, harmonic distortion, etc., for each time window to obtain a value. The value can correspond to or represent one of the metrics for voltage waveform over the time interval. The determined metrics can indicate the (first set of) characteristics or fingerprints of the voltage waveform.

The time interval can be predetermined, for instance, according to the configuration of the metering system. The configuration can be synced or shared across multiple metering systems within the utility grid. For example, the data processing system (e.g., server, administrator device, or remote device) can broadcast the configuration to multiple metering systems, such that the metrics are determined by the metering systems over a similar time interval. In some cases, the time interval can be configured by the operator of the data processing system or individual metering systems.

At ACT 306, the metering system can generate a model waveform based on a sinusoidal waveform. The metering system can fit a sinusoidal waveform to the voltage waveform to generate the model waveform. In some cases, the model waveform can correspond to the sinusoidal waveform. The sinusoidal waveform can refer to an ideal sine wave configured for fitting to the voltage waveform (e.g., measured voltage waveform). The metering system can receive the sinusoidal waveform from a global template provided by the data processing system or configured by the utility operators. Other metering systems can receive the same or similar global template for the sinusoidal waveform to be fitted with their respective measured voltage waveforms.

Fitting the sinusoidal waveform to the voltage waveform can refer to normalizing the voltage waveform to a template or ideal waveform, such as adjusting the amplitude of the voltage waveform to fit the amplitude of the ideal sinusoidal waveform (e.g., having similar maximum or minimum peaks for the time interval), adjusting the frequency of the voltage waveform to fit the frequency of the ideal sinusoidal waveform, etc. By fitting the voltage waveform to the ideal sinusoidal waveform, differences, anomalies, or deviations between multiple voltage waveforms can be identified (e.g., from different time intervals or across metering systems).

At ACT 308, the metering system can determine the second plurality of metrics (e.g., second set of metrics) for the voltage waveform over the time interval based on a difference between the voltage waveform and the model waveform. The time interval can be the same time interval as for the first set of metrics. The metering system can determine the difference between the waveforms to generate or determine the second set of metrics via at least one of the statistical techniques.

For example, the metering system can generate at least one of the second set of metrics based on an error metric between the voltage waveform and the model waveform fit based on the sinusoidal wave to the voltage waveform. The error metric can include or correspond to the fit RMSE mean, fit RMSE standard deviation, or fit MAE, among other statistical techniques. In another example, the metering system can generate at least one of the second set of metrics based on at least one of a mean amplitude or a mean frequency of the model waveform fit based on a sinusoidal wave to the voltage waveform. The mean amplitude can include or correspond to the fit amplitude mean RMS, fit amplitude standard deviation, etc. The mean frequency can include or correspond to fit frequency mean, fit frequency standard deviation, etc. The metering system can utilize other types of statistical techniques or metrics to determine the second set of metrics representing the difference between the voltage waveform and the model waveform (e.g., the voltage waveform fitted to the sinusoidal waveform or vice versa).

At ACT 310, the metering system can construct a data structure including the first plurality of metrics, the second plurality of metrics, and an identifier for the location. The identifier can be associated with the metering system. The identifier can be used as a lookup key by the data processing system or other authorized devices of the utility grid to obtain information regarding the metering system, such as its location, coupled secondary transformer, electrical information, etc.

In some cases, the metering system can construct a data structure including multiple data structures. For example, the metering system can generate a first data structure with or including first values for the first plurality of metrics over a first time interval of the voltage waveform (e.g., first statistical techniques performed over a first set of time windows), and first values for the second plurality of metrics over the first time interval of the voltage waveform (e.g., second statistical techniques performed over the first set of time windows). The metering system can generate a second data structure with second values for the first plurality of metrics over a second time interval of the voltage waveform (e.g., first statistical techniques performed over a second set of time windows), and second values for the second plurality of metrics over the second time interval of the voltage waveform (e.g., second statistical techniques performed over the second set of time windows). The metering system can generate a third data structure with third values for the first plurality of metrics over a third time interval of the voltage waveform (e.g., first statistical techniques performed over a third set of time windows), and third values for the second plurality of metrics over the third time interval of the voltage waveform (e.g., second statistical techniques performed over the third set of time windows). After generating these data structures, the metering system can construct a data structure to include multiple generated data structures. The metering system can accumulate multiple data structures to construct one data structure for uploading to the data processing system over a batch upload process to reduce network traffic, resource, or bandwidth.

At ACT 312, the metering system can determine whether ready to transmit the data structure (or other information) to the data processing system. The metering system can determine whether ready to transmit based on the configuration of the metering system. The metering system can receive the configuration or be configured by the data processing system. For example, based on the configuration, the metering system can determine whether the number of data structures for constructing a single data structure satisfied an upload threshold for the batch upload process. If the upload threshold is set to three time intervals, the metering system can determine that it is ready to transmit data when the data structure includes at least three data structures (e.g., determined metrics over three time intervals).

In another example, if the upload threshold is configured as a minimum size (e.g., minimum duration of time interval) for the data structure, the metering system can be ready to transmit when the data structure is constructed with a sufficient number of metrics over at least the minimum duration of time interval. In further example, the metering system can determine whether other metering systems are ready to transmit their respective data structures. The metering system can be in communication directly with other metering systems or receive status updates of other metering systems from the data processing system. In this example, if the upload threshold is set to at least three metering systems, the metering system can be ready to transmit when at least two other metering systems have constructed their respective data structures. The other metering systems can be relatively close to the metering system, such as within a predefined radius or distance (e.g., 100 feet, 150 feet, or 200 feet).

In some cases, the metering system can determine whether ready to transmit based on the availability of the data processing system. For example, the metering system can store the data structure in the local data repository or queue the data structure for transmission. Upon receiving an indication (e.g., request or signal) to transmit data from the data processing system, the metering system can determine that it is ready to transmit. When ready, the metering system can proceed to ACT 314. Otherwise, the metering system can queue the data structure for transmission or perform other operations until it is ready to transmit, such as continuing to construct the data structure at ACT 310.

At ACT 314, the metering system can provide the data structure to the data processing system remote from the metering system, such as to cause the data processing system to evaluate the performance of the utility grid. The evaluation of the performance of the utility grid can refer to analyzing the voltage waveform to determine the condition of the electricity experienced by individual metering systems. The metering system can provide the data structure to the data processing system over the batch upload process to minimize network resource consumption.

In various cases, other metering systems can provide their respective data structures to the data processing system. For example, a second metering system at a second location on the utility grid can generate a second data structure with values for the first plurality of metrics over the time interval of a second voltage waveform, and values for the second plurality of metrics over the time interval of the second voltage waveform. A third metering system at a third location on the utility grid can generate a third data structure with values for the first plurality of metrics over the time interval of a third voltage waveform, and values for the second plurality of metrics over the time interval of the third voltage waveform. The second metering system can provide the second data structure to the data processing system. The third metering system can provide the third data structure to the data processing system. In some other cases, the second and third metering systems can forward their constructed data structures to the first metering system (or to another metering system) to upload multiple data structures (or a combined data structure) via the batch upload process.

At ACT 316, the data processing system can determine whether it has received the data structure from one or more metering systems. If the data processing system is expecting the data structure (e.g., a first request sent to the metering system(s)), and the data processing system does not receive the data structure within a predetermined time duration, the data processing system may transmit another request (e.g., second request). In this case, the metering system can either re-transmit the constructed data structure or initiate the data collection process (e.g., if the first request was not received by the metering system). In some other cases, the data processing system may receive an insufficient amount of information from the metering system(s), e.g., metrics are determined over a time interval that is less than a predefined time interval, received data structures from a number of metering systems that is less than a predefined number of metering systems, etc. In such cases, the data processing system can transmit a request for data structures from one or more metering systems. If the data processing system received the data structure (e.g., a sufficient amount of information), the data processing system can proceed to ACT 318.

At ACT 318, the data processing system can determine a topological relationship between the metering systems (e.g., the first metering system, the second metering system, and the third metering system) based on the data structures (e.g., the first data structure, the second data structure, and the third data structure). For example, the data processing system can compare the metrics between the data structures from metering systems located relatively close to each other (e.g., within the predefined distance) based on the location associated with the respective identifiers. The data processing system can compare the metrics to determine the similarities or differences between the characteristics, behaviors, or fingerprints of the electrical signals (e.g., fluctuations, increases, decreases, delays, among other patterns) measured by individual metering systems (e.g., sensors of the metering systems). For the metering systems measuring similar voltage characteristics or fingerprints, the data processing system can determine that these metering systems are associated with the same group (e.g., connected to the same secondary transformer). The data processing system can determine the voltage characteristics based on the metrics of each data structure. For the metering systems experiencing different voltage characteristics, the data processing system can determine that the metering systems are associated with different groups (e.g., connected to different secondary transformers), for example. The data processing system can perform other features or functionalities to analyze the condition of the electricity distributed to individual metering systems according to the data structures.

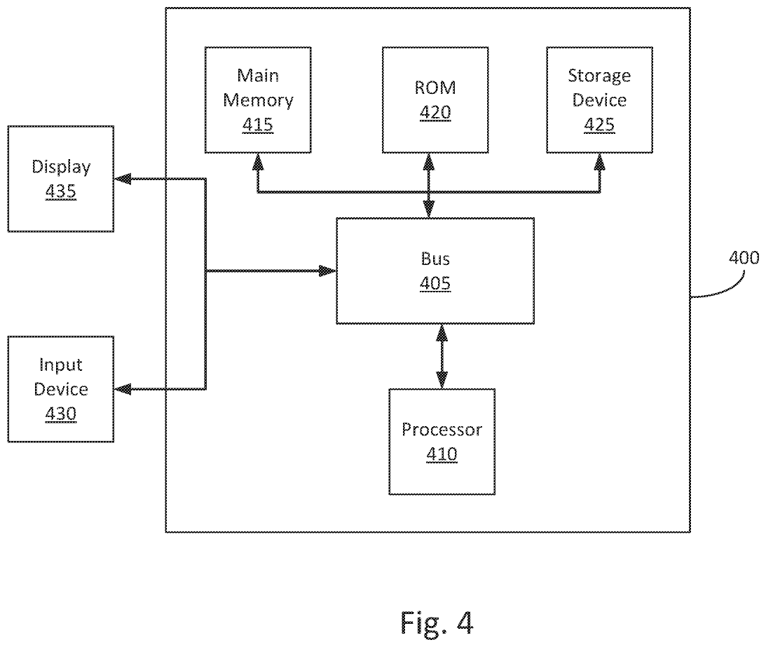

FIG. 4 is a block diagram of an example computer system 400. The computer system or computing device 400 can include or be used to implement the data processing system 150, or its components such as the data processing system 150. The computing system 400 includes at least one bus 405 or other communication components for communicating information and at least one processor 410 or processing circuit coupled to the bus 405 for processing information. The computing system 400 can also include one or more processors 410 or processing circuits coupled to the bus for processing information. The computing system 400 also includes at least one main memory 415, such as a random access memory (RAM) or other dynamic storage devices, coupled to the bus 405 for storing information, and instructions to be executed by the processor 410. The main memory 415 can also be used for storing position information, utility grid data, command instructions, device status information, environmental information within or external to the utility grid, information on characteristics of electricity, or other information during execution of instructions by the processor 410. The computing system 400 may further include at least one read only memory (ROM) 420 or other static storage device coupled to the bus 405 for storing static information and instructions for the processor 410. A storage device 425, such as a solid state device, magnetic disk or optical disk, can be coupled to the bus 405 to persistently store information and instructions.

The computing system 400 may be coupled via the bus 405 to a display 435, such as a liquid crystal display, or active matrix display, for displaying information to a user such as an administrator of the data processing system or the utility grid. An input device 430, such as a keyboard or voice interface may be coupled to the bus 405 for communicating information and commands to the processor 410. The input device 430 can include a touch screen display 435. The input device 430 can also include a cursor control, such as a mouse, a trackball, or cursor direction keys, for communicating direction information and command selections to the processor 410 and for controlling cursor movement on the display 435. The display 435 can be part of the data processing system 150, the metering system 201, or other components of at least one of FIGS. 1-2.

The processes, systems and methods described herein can be implemented by the computing system 400 in response to the processor 410 executing an arrangement of instructions contained in main memory 415. Such instructions can be read into main memory 415 from another computer-readable medium, such as the storage device 425. Execution of the arrangement of instructions contained in main memory 415 causes the computing system 400 to perform the illustrative processes described herein. One or more processors in a multi-processing arrangement may also be employed to execute the instructions contained in main memory 415. Hard-wired circuitry can be used in place of or in combination with software instructions together with the systems and methods described herein. Systems and methods described herein are not limited to any specific combination of hardware circuitry and software.

Although an example computing system has been described in FIG. 4, the subject matter including the operations described in this specification can be implemented in other types of digital electronic circuitry, or in computer software, firmware, or hardware, including the structures disclosed in this specification and their structural equivalents, or in combinations of one or more of them.

### FURTHER EXAMPLES

The following examples pertain to further embodiments, from which numerous permutations and configurations will be apparent.

Example 1 includes a system, comprising: a metering system at a location downstream from a substation on a utility grid that distributes electricity, the metering system comprising memory and one or more processors to: receive data samples of a voltage waveform corresponding to the electricity distributed at the location; determine a first plurality of metrics for the voltage waveform over a time interval via a statistical technique; determine a second plurality of metrics for the voltage waveform over the time interval based on a difference between the voltage waveform and a model waveform; construct a data structure comprising the first plurality of metrics, the second plurality of metrics, and an identifier for the location; and provide the data structure to a data processing system remote from the metering system to cause the data processing system to evaluate a performance of the utility grid.

Example 2 includes the subject matter of Example 1, comprising: the metering system to generate the model waveform based on a sinusoidal waveform.

Example 3 includes the subject matter of any of Examples 1 and 2, comprising: the metering system to fit a sinusoidal waveform to the voltage waveform to generate the model waveform.

Example 4 includes the subject matter of any of Examples 1 through 3, wherein the data structure comprises a plurality of data structures, comprising the metering system to: generate a first data structure of the plurality of data structures with first values for the first plurality of metrics over a first time interval of the voltage waveform, and first values for the second plurality of metrics over the first time interval of the voltage waveform; generate a second data structure of the plurality of data structures with second values for the first plurality of metrics over a second time interval of the voltage waveform, and second values for the second plurality of metrics over the second time interval of the voltage waveform; generate a third data structure of the plurality of data structures with third values for the first plurality of metrics over a third time interval of the voltage waveform, and third values for the second plurality of metrics over the third time interval of the voltage waveform; and provide the data structure comprising the plurality of data structures to the data processing system over a batch upload process.

Example 5 includes the subject matter of any of Examples 1 through 4, comprising: a second metering system at a second location on the utility grid to: generate a second data structure with values for the first plurality of metrics over the time interval of a second voltage waveform, and values for the second plurality of metrics over the time interval of the second voltage waveform; and provide the second data structure to the data processing system; and a third metering system at a third location on the utility grid to: generate a third data structure with values for the first plurality of metrics over the time interval of a third voltage waveform, and values for the second plurality of metrics over the time interval of the third voltage waveform; and provide the third data structure to the data processing system.

Example 6 includes the subject matter of any of Examples 1 through 5, comprising: the data processing system to determine a topological relationship between the metering system, the second metering system, and the third metering system based on the data structure, the second data structure, and the third data structure.

Example 7 includes the subject matter of any of Examples 1 through 6, wherein the metering system comprises: one or more sensors to measure the voltage waveform to provide the data samples.

Example 8 includes the subject matter of any of Examples 1 through 7, wherein the metering system is communicatively coupled with one or more sensors, the one or more sensors to measure the voltage waveform to provide the data samples.

Example 9 includes the subject matter of any of Examples 1 through 8, comprising: the metering system to generate at least one of the second plurality of metrics based on an error metric between the voltage waveform and the model waveform fit based on a sinusoidal waveform to the voltage waveform.

Example 10 includes the subject matter of any of Examples 1 through 9, comprising: the metering system to generate at least one of the second plurality of metrics based on at least one of a mean amplitude or a mean frequency of the model waveform fit based on a sinusoidal waveform to the voltage waveform.

Example 11 includes a method, comprising: receiving, by a metering system comprising memory and one or more processors, data samples of a voltage waveform corresponding to the electricity distributed at the location, the metering system at a location downstream from a substation on a utility grid that distributes electricity; determining, by the metering system, a first plurality of metrics for the voltage waveform over a time interval via a statistical technique; determining, by the metering system, a second plurality of metrics for the voltage waveform over the time interval based on a difference between the voltage waveform and a model waveform; constructing, by the metering system, a data structure comprising the first plurality of metrics, the second plurality of metrics, and an identifier for the location; and providing, by the metering system, the data structure to a data processing system remote from the metering system to cause the data processing system to evaluate a performance of the utility grid.

Example 12 includes the subject matter of Example 11, comprising: generating, by the metering system, the model waveform based on a sinusoidal waveform.

Example 13 includes the subject matter of Examples 11 and 12, comprising: fitting, by the metering system, a sinusoidal waveform to the voltage waveform to generate the model waveform.

Example 14 includes the subject matter of Examples 11 through 13, wherein the data structure comprises a plurality of data structures, comprising: generating, by the metering system, a first data structure of the plurality of data structures with first values for the first plurality of metrics over a first time interval of the voltage waveform, and first values for the second plurality of metrics over the first time interval of the voltage waveform; generating, by the metering system, a second data structure of the plurality of data structures with second values for the first plurality of metrics over a second time interval of the voltage waveform, and second values for the second plurality of metrics over the second time interval of the voltage waveform; generating, by the metering system, a third data structure of the plurality of data structures with third values for the first plurality of metrics over a third time interval of the voltage waveform, and third values for the second plurality of metrics over the third time interval of the voltage waveform; and providing, by metering system, the data structure comprising the plurality of data structures to the data processing system over a batch upload process.

Example 15 includes the subject matter of Examples 11 through 14, comprising: generating, by a second metering system at a second location on the utility grid, a second data structure with values for the first plurality of metrics over the time interval of a second voltage waveform, and values for the second plurality of metrics over the time interval of the second voltage waveform; providing, by the second metering system, the second data structure to the data processing system; generating, by a third metering system at a third location on the utility grid, a third data structure with values for the first plurality of metrics over the time interval of a third voltage waveform, and values for the second plurality of metrics over the time interval of the third voltage waveform; and providing, by the third metering system, the third data structure to the data processing system.

Example 16 includes the subject matter of Examples 11 through 15, comprising: determining, by the data processing system, a topological relationship between the metering system, the second metering system, and the third metering system based on the data structure, the second data structure, and the third data structure.

Example 17 includes the subject matter of Examples 11 through 16, comprising: detecting, by one or more sensors of the metering system, the voltage waveform to provide the data samples.

Example 18 includes the subject matter of Examples 11 through 17, wherein the metering system is communicatively coupled with one or more sensors, comprising: detecting, by the one or more sensors, the voltage waveform to provide the data samples.

Example 19 includes a non-transitory computer readable storage medium comprising processor executable instructions that, when executed by one or more processors of a metering system, cause the metering system to: receive data samples of a voltage waveform corresponding to the electricity distributed at the location; determine a first plurality of metrics for the voltage waveform over a time interval via a statistical technique; determine a second plurality of metrics for the voltage waveform over the time interval based on a difference between the voltage waveform and a model waveform; construct a data structure comprising the first plurality of metrics, the second plurality of metrics, and an identifier for the location; and provide the data structure to a data processing system remote from the metering system to cause the data processing system to evaluate a performance of a utility grid.

Example 20 includes the subject matter of Example 19, wherein the instructions further comprise instructions to: generate the model waveform based on a sinusoidal waveform.

Some of the descriptions herein emphasize the structural independence of the aspects of the system components (e.g., arbitration component) and illustrate one grouping of operations and responsibilities of these system components. Other groupings that execute similar overall operations are understood to be within the scope of the present application. Modules can be implemented in hardware or as computer instructions on a non-transient computer-readable storage medium, and modules can be distributed across various hardware- or computer-based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C #, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

The systems and methods described herein may be embodied in other specific forms without departing from the characteristics thereof. Scope of the systems and methods described herein is thus indicated by the appended claims, rather than the foregoing description, and changes that come within the meaning and range of equivalency of the claims are embraced therein.

While this specification contains many specific implementation details, these should not be construed as limitations on the scope of any inventions or of what can be claimed, but rather as descriptions of features specific to particular embodiments of particular aspects. Certain features described in this specification in the context of separate embodiments can also be implemented in combination in a single embodiment. Conversely, various features described in the context of a single embodiment can also be implemented in multiple embodiments separately or in any suitable subcombination. Moreover, although features can be described above as acting in certain combinations and even initially claimed as such, one or more features from a claimed combination can in some cases be excised from the combination, and the claimed combination can be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system components in the embodiments described above should not be understood as requiring such separation in all embodiments, and it should be understood that the described program components and systems can generally be integrated in a single software product or packaged into multiple software products.

Thus, particular embodiments of the subject matter have been described. In some cases, the actions recited in the claims can be performed in a different order and still achieve desirable results. In addition, the processes depicted in the accompanying figures do not necessarily require the particular order shown, or sequential order, to achieve desirable results.

What is claimed is:

1. A system, comprising:
a metering system at a location downstream from a substation on a utility grid that distributes electricity, the metering system comprising memory and one or more processors to:
receive data samples of a voltage waveform corresponding to the electricity distributed at the location;
determine a first plurality of metrics for the voltage waveform over a time interval via a statistical technique;
determine a second plurality of metrics for the voltage waveform over the time interval based on a difference between the voltage waveform and a model waveform;
construct a data structure comprising the first plurality of metrics, the second plurality of metrics, and an identifier for the location; and
provide the data structure to a data processing system remote from the metering system to cause the data processing system to evaluate a performance of the utility grid.

2. The system of claim 1, comprising:
the metering system to generate the model waveform based on a sinusoidal waveform.

3. The system of claim 1, comprising:
the metering system to fit a sinusoidal waveform to the voltage waveform to generate the model waveform.

4. The system of claim 1, wherein the data structure comprises a plurality of data structures, comprising the metering system to:
generate a first data structure of the plurality of data structures with first values for the first plurality of metrics over a first time interval of the voltage waveform, and first values for the second plurality of metrics over the first time interval of the voltage waveform;
generate a second data structure of the plurality of data structures with second values for the first plurality of metrics over a second time interval of the voltage waveform, and second values for the second plurality of metrics over the second time interval of the voltage waveform;
generate a third data structure of the plurality of data structures with third values for the first plurality of metrics over a third time interval of the voltage waveform, and third values for the second plurality of metrics over the third time interval of the voltage waveform; and
provide the data structure comprising the plurality of data structures to the data processing system over a batch upload process.

5. The system of claim 1, comprising:
a second metering system at a second location on the utility grid to:
generate a second data structure with values for the first plurality of metrics over the time interval of a second voltage waveform, and values for the second plurality of metrics over the time interval of the second voltage waveform; and
provide the second data structure to the data processing system; and
a third metering system at a third location on the utility grid to:
generate a third data structure with values for the first plurality of metrics over the time interval of a third voltage waveform, and values for the second plurality of metrics over the time interval of the third voltage waveform; and
provide the third data structure to the data processing system.

6. The system of claim 5, comprising:
the data processing system to determine a topological relationship between the metering system, the second metering system, and the third metering system based on the data structure, the second data structure, and the third data structure.

7. The system of claim 1, wherein the metering system comprises:
one or more sensors to measure the voltage waveform to provide the data samples.

8. The system of claim 1, wherein the metering system is communicatively coupled with one or more sensors, the one or more sensors to measure the voltage waveform to provide the data samples.

9. The system of claim 1, comprising:
the metering system to generate at least one of the second plurality of metrics based on an error metric between the voltage waveform and the model waveform fit based on a sinusoidal waveform to the voltage waveform.

10. The system of claim 1, comprising:
the metering system to generate at least one of the second plurality of metrics based on at least one of a mean amplitude or a mean frequency of the model waveform fit based on a sinusoidal waveform to the voltage waveform.

11. A method, comprising:
receiving, by a metering system comprising memory and one or more processors, data samples of a voltage waveform corresponding to the electricity distributed at the location, the metering system at a location downstream from a substation on a utility grid that distributes electricity;
determining, by the metering system, a first plurality of metrics for the voltage waveform over a time interval via a statistical technique;
determining, by the metering system, a second plurality of metrics for the voltage waveform over the time interval based on a difference between the voltage waveform and a model waveform;
constructing, by the metering system, a data structure comprising the first plurality of metrics, the second plurality of metrics, and an identifier for the location; and
providing, by the metering system, the data structure to a data processing system remote from the metering system to cause the data processing system to evaluate a performance of the utility grid.

12. The method of claim 11, comprising:
generating, by the metering system, the model waveform based on a sinusoidal waveform.

13. The method of claim 11, comprising:
fitting, by the metering system, a sinusoidal waveform to the voltage waveform to generate the model waveform.

14. The method of claim 11, wherein the data structure comprises a plurality of data structures, comprising:
generating, by the metering system, a first data structure of the plurality of data structures with first values for the first plurality of metrics over a first time interval of the voltage waveform, and first values for the second plurality of metrics over the first time interval of the voltage waveform;
generating, by the metering system, a second data structure of the plurality of data structures with second values for the first plurality of metrics over a second time interval of the voltage waveform, and second values for the second plurality of metrics over the second time interval of the voltage waveform;
generating, by the metering system, a third data structure of the plurality of data structures with third values for the first plurality of metrics over a third time interval of the voltage waveform, and third values for the second plurality of metrics over the third time interval of the voltage waveform; and
providing, by metering system, the data structure comprising the plurality of data structures to the data processing system over a batch upload process.

15. The method of claim 11, comprising:
generating, by a second metering system at a second location on the utility grid, a second data structure with values for the first plurality of metrics over the time interval of a second voltage waveform, and values for the second plurality of metrics over the time interval of the second voltage waveform;
providing, by the second metering system, the second data structure to the data processing system;
generating, by a third metering system at a third location on the utility grid, a third data structure with values for the first plurality of metrics over the time interval of a third voltage waveform, and values for the second plurality of metrics over the time interval of the third voltage waveform; and
providing, by the third metering system, the third data structure to the data processing system.

16. The method of claim 15, comprising:
determining, by the data processing system, a topological relationship between the metering system, the second metering system, and the third metering system based on the data structure, the second data structure, and the third data structure.

17. The method of claim 11, comprising:
detecting, by one or more sensors of the metering system, the voltage waveform to provide the data samples.

18. The method of claim 11, wherein the metering system is communicatively coupled with one or more sensors, comprising:
detecting, by the one or more sensors, the voltage waveform to provide the data samples.

19. A non-transitory computer readable storage medium comprising processor executable instructions that, when executed by one or more processors of a metering system, cause the metering system to:
receive data samples of a voltage waveform corresponding to the electricity distributed at the location;
determine a first plurality of metrics for the voltage waveform over a time interval via a statistical technique;
determine a second plurality of metrics for the voltage waveform over the time interval based on a difference between the voltage waveform and a model waveform;
construct a data structure comprising the first plurality of metrics, the second plurality of metrics, and an identifier for the location; and
provide the data structure to a data processing system remote from the metering system to cause the data processing system to evaluate a performance of a utility grid.

20. The non-transitory computer readable storage medium of claim 19, wherein the instructions further comprise instructions to:
generate the model waveform based on a sinusoidal waveform.
